(19) United States
(12) Patent Application Publication
(10) Pub. No.: US 2026/0019036 A1
(43) Pub. Date: Jan. 15, 2026

(54) MLINC

(71) Applicant: RHEINISCH-WESTFÄLISCHE TECHNISCHE HOCHSCHULE (RWTH) AACHEN, Aachen (DE)

(72) Inventors: Stefan MÜLLER, Aachen (DE); Renato NEGRA, Aachen (DE)

(73) Assignee: RHEINISCH-WESTFÄLISCHE TECHNISCHE HOCHSCHULE (RWTH) AACHEN, Aachen (DE)

(21) Appl. No.: 18/839,715

(22) PCT Filed: Feb. 7, 2023
(86) PCT No.: PCT/EP2023/052924

§ 371 Date: Apr. 29, 2025

(30) Foreign Application Priority Data
Feb. 22, 2022 (DE) 102022104165.4

(51) Int. Cl. H03F 1/02; H03F 3/21; H03F 3/213

(52) U.S. Cl. CPC H03F 1/0205; H03F 3/211; H03F 3/213; H03F 2200/451

(57) ABSTRACT

A multilevel linear amplifier with non-linear components, MLINC (1), for a radio frequency transmitter, the MLINC (1) comprising a first outphasing amplifier (2) adapted to receive a first set of input signals (S11, S12) and providing a first intermediate signal (S1) with a stepped envelope depending on a controlled portion (θc1) of a phase modulation in the first set of input signals (S11, S12); a second outphasing amplifier (3) adapted to receive a second set of input signals (S21, S22) and to provide a second intermediate signal (S2) with a stepped envelope depending on a controlled portion (0c2) of a phase modulation in the second set of input signals (S21, S22); and a combiner (6) adapted to combine the first and second intermediate signals (S2) into an output signal (Sout) having an envelope linearized due to a phase symmetry of the first and second intermediate signals (S1, S2).

### TECHNICAL AREA

The invention relates to a multilevel linear amplifier with non-linear components (MLINC) with the features of the preamble in claim 1 and a method for operating an MLINC.

The following background is intended only to provide information necessary to understand the context of the inventive ideas and concepts disclosed herein. Therefore, this background section may include patentable subject-matter and should not be considered prior art.

### BACKGROUND

The demand for wireless communication with high data rates is constantly growing. To increase the data rate, both the linearity and the bandwidth of the circuits in radio frequency transmitters must be increased. This leads to increasing power consumption of the associated cell phones and base stations, as there is an inherent trade-off between linearity and power efficiency in the power amplifiers (PA), which are typically the most power consuming part of the overall radio frequency transmitter.

The present invention solves the trade-off between linearity and power efficiency while enabling high bandwidth modulation.

The invention is now based on the problem of improving the trade-off between linearity and power efficiency. Simultaneously, high bandwidth modulation can be provided.

### SUMMARY

The purpose of this summary section is to introduce a selection of features and concepts of embodiments of the invention, which are explained further below in the description. This summary is not intended to identify important or essential features of the claimed subject-matter, nor is it intended to limit the scope of the claimed subject-matter.

According to the invention, the above problem is solved by the features of the independent claims.

Specifically, the problem is solved by a multilevel linear amplifier with non-linear components (also called MLINC) for a radio frequency transmitter or of a radio frequency transmitter.

The MLINC comprises a first outphasing amplifier. The first outphasing amplifier is adapted to receive a first set of input signals. The first outphasing amplifier is adapted to provide a first intermediate signal. The first intermediate signal may be based solely on the first set of input signals. The first intermediate signal has a stepped or step-shaped envelope. The step shape or the envelope of the first intermediate signal depends on a (first) controlled portion of a (first) phase modulation in the first set of input signals.

The MLINC comprises a second outphasing amplifier. The second outphasing amplifier is adapted to receive a second set of input signals. The second outphasing amplifier is adapted to provide a second intermediate signal. The second intermediate signal can be based solely on the second set of input signals. The second intermediate signal has a stepped envelope. The step shape or the envelope of the second intermediate signal depends on a (second) controlled portion of a (second) phase modulation in the second set of input signals.

The MLINC comprises a combiner. The combiner is adapted to combine the first and second intermediate signals into a (in particular common or single) output signal. The output signal has a linearized envelope due to a phase symmetry of the first and second intermediate signals.

The invention has the advantage of providing an improved trade-off between linearity and power efficiency of the MLINC. In addition, a high bandwidth modulation can be provided.

In particular, it is to be understood herein that the respective input signals are already phase modulated by the (e.g., respective first and second) phase modulation before they are received by the MLINC. Within the MLINC described herein, for example, no (further) modulation, namely amplitude modulation or phase modulation, may be provided.

The phase symmetry of the first and second intermediate signals can be understood to mean that the (first and second) phase modulation is adjusted in such a way that the first and second outphasing amplifiers have phase shifts at the output that are equal in amount but different from each other, i.e. phase shifts in opposite directions.

The first set of input signals may differ in phase and/or amplitude from the second set of input signals such that the two intermediate signals are equal in magnitude. For example, the first and second set of input signals can be symmetrical but out of phase in opposite directions, for example by means of opposite outphasing angles. Also, the input signals of the first set of input signals may be phase shifted symmetrically but in opposite directions, for example by means of opposite first and second controlled portions of the (first) phase modulation. The same can apply to the input signals of the second set of input signals. These can be symmetrical, but phase shifted in opposite directions, for example by means of opposing first and second controlled portions of the (second) phase modulation.

The step shape or stepped envelope can be understood to mean that a dedicated envelope level can be adjusted by the controlled portion of the phase modulation. The controlled portion may be the same in each of the first and second sets of input signals. In particular, the first and second controlled portions can be the same, for example in each case. Here, the term “controlled” may be understood to mean that programming takes place during operation or before operation of the MLINC in the radio frequency transmitter. In an example, this can be carried out in the sense of a software-defined radio or other processor units mentioned below.

Advantageous embodiments of the invention are provided in the dependent claims.

The input signals of the first and second set of input signals can have the same amplitudes.

This simplifies the wiring of the MLINC or the radio frequency transmitter. Costs can be saved.

The input signals of the first set of input signals can have the same (first) constant envelope. The input signals of the second set of input signals can have the same (second) constant envelope. The input signals of the first and second set of input signals can have the same (first and second) constant envelope.

This also simplifies the wiring of the MLINC or the radio frequency transmitter and thus saves operating costs.

The first set of input signals and the second set of input signals may include phase modulated input signals. For example, the input signals of the first and second set of input signals can be purely, i.e. exclusively, phase modulated.

This can also save costs for the wiring. System performance can also be increased as a result.

The controlled portion of the phase modulation in the first set of input signals may be equal to the controlled portion of the phase modulation in the second set of input signals.

This improves circuit symmetry and reduces circuit complexity.

The first outphasing amplifier and the second outphasing amplifier can be non-isolating outphasing amplifiers.

This can ensure effective coupling in the respective outphasing amplifiers, which can facilitate symmetrical phase matching.

The first outphasing amplifier and the second outphasing amplifier may each have (e.g. two) input nodes and an output node. The input nodes may form the inputs of the MLINC. Further, the first and second outphasing amplifiers may each have a chireix combiner. Each of the chireix combiners may have passive components. The passive components may be complementary to each other. The passive components may have complex conjugate admittances. Each of the chireix combiners may have 24 lines with respect to a carrier frequency λ of the radio frequency transmitter.

The λ/4 lines with respect to the carrier frequency λ of the radio frequency transmitter can each be connected between the output node and a corresponding one of the input nodes. The passive components can each be connected between a corresponding one of the input nodes and ground. The λ/4 lines with respect to the carrier frequency λ of the radio frequency transmitter and the passive components can each have a common connection node.

Alternatively, the λ/4 lines with respect to the carrier frequency λ of the radio frequency transmitter and the passive components can each be connected in series one behind the other in signal direction, for example between the respective input node and output node. The λ/4 lines with respect to the carrier frequency λ of the radio frequency transmitter and the passive components can each have the common connection node.

In an alternative, a respective non-isolating combiner structure may be used, for example instead of the chireix combiner. The respective non-isolating combiner structure may be adapted to change a load impedance of the respective amplifier elements via a phase of the respective input signal. As an example, the non-isolating combiner structure may correspond to the structure T′₂ₚ in FIG. 9 from IEEE Transactions On Circuits And Systems-I: Regular Papers, Vol. 64, No. 5, May 2017; Özen et al: “A Generalized Combiner Synthesis Technique for Class-E Outphasing Transmitters”.

The combiner can have (two) input nodes. The input nodes of the combiner may each be connected to one of the output nodes of the first and second outphasing amplifiers. The combiner may have an output node. The output node may form an output of the MLINC. The combiner may have an isolating power combiner. The isolating power combiner may be a Wilkinson combiner. The power combiner may have a resistive clement. The resistive element may be connected between the (two) input nodes of the combiner. The power combiner may have λ/4 lines with respect to the carrier frequency λ of the radio frequency transmitter. The λ/4 lines with respect to the carrier frequency λ of the radio frequency transmitter can cach be connected between the output node of the combiner and the (two) input nodes of the combiner.

The MLINC can be an integrated circuit, for example a chip. The MLINC can be manufactured at least partially using strip line technology. For example, the strip lines used may comprise microstrip line, symmetrical stripline, coplanar line, or symmetrical/unbalanced double-band line. Thus, the λ/4 lines with respect to the carrier frequency λ of the radio frequency transmitter may each have essentially the same line width. The strip line technology can be adapted to a Z₀ system, for example a 50 Ohm system, so that the λ/4 lines (at least of the power combiner) with respect to the carrier frequency λ of the radio frequency transmitter are \sqrt{2} Z₀, for example approximately 71 ohms. The line width or the characteristic impedance of the respective λ/4 lines with respect to the carrier frequency λ of the radio frequency transmitter can be set to a characteristic impedance value, \sqrt{2} Z₀, for example approximately 71 ohms. For example, the respective λ/4 lines (at least the chireix combiner) with respect to the carrier frequency λ of the radio frequency transmitter can be set to a characteristic impedance value, Z₀, for example approximately 50 ohms.

The characteristic impedance of the strip line can depend on the strip line substrate used for the MLINC and/or the strip line width or be adapted accordingly. The above-mentioned resistor of the power combiner can have a resistance value of 2Z₀, for example 100 ohms.

In this way, a simple circuit arrangement can be provided that is inexpensive to manufacture.

The first outphasing amplifier may have a first set of amplifier elements. The second outphasing amplifier may have a second set of amplifier elements. The first set of amplifier elements may have a same number and/or type of amplifier elements. The second set of amplifier elements may have a same number and/or type of amplifier elements. The first set of amplifier elements and the second set of amplifier elements may have the same number and type of amplifier elements.

The symmetry and circuit complexity of the MLINC can thus be improved.

A respective amplifier element of the first and second set of amplifier elements may be downstream of a corresponding one of the input nodes of the first and second outphasing amplifiers in the signal direction. For example, a respective amplifier element of the first and second set of amplifier elements may be connected between a corresponding one of the input nodes of the first and second outphasing amplifiers and a corresponding one of the passive components of the first and second Chireix combiner. Thus, a respective amplifier element may be connected between a corresponding input node and a corresponding connection node of one of the first and second outphasing amplifiers.

This results in an optimized phasing structure.

In an example, a power supply can be provided for the amplifier elements of the first and second outphasing amplifiers. The power supply can be symmetrical. For example, the power supply may be the same for all amplifier elements of the first and second outphasing amplifiers, in particular providing an equal power/voltage. An arrangement of voltage supply points may also be the same for all amplifier elements of the first and second outphasing amplifiers.

Individual circuit blocks, for example the first and/or second outphasing amplifier, and/or the power combiner of the MLINC can be arranged in a circuit-symmetrical manner.

A simplified circuit can be provided.

All input signals can include an information portion that maps the data to be transmitted.

The above problem is also solved by a method for operating a multilevel linear amplifier with non-linear components (MLINC) of a radio frequency transmitter or for a radio frequency transmitter.

The method comprises receiving a first and second set of input signals. The receiving preferably takes place simultaneously.

The method comprises providing first and second intermediate signals each having a stepped envelope dependent on a controlled portion of a phase modulation in a corresponding one of the first and second sets of input signals. This is preferably provided simultaneously. The first set of input signals is preferably provided to a single common first intermediate signal. The second set of input signals is preferably provided to a single common second intermediate signal.

The method comprises combining the first and second intermediate signals into a common output signal which has an envelope linearized due to a phase symmetry of the first and second intermediate signals. Combining is preferably performed simultaneously. The first and second intermediate signals are preferably combined to form a single common output signal.

In other words, the invention relates to the use of highly efficient, non-isolating PAs in a multilevel LINC architecture. This allows the transmission waveform to be controlled by phase modulation only. This approach increases the possible modulation bandwidth and makes signal generation much simpler and cheaper compared to the prior art. In particular, the radio frequency transmitter presented herein can be installed in mobile network infrastructure or cell phones.

Although some of the aspects described above have been described in relation to the method, these aspects may also apply to the MLINC. Similarly, the aspects described above in relation to the MLINC may apply to the method in a corresponding manner.

It will be apparent to the skilled person that the explanations set forth herein may be implemented using hardware circuitry, software means, or a combination thereof. The software means may be associated with programmed microprocessors, ASICs (application specific integrated circuits) and/or DSPs (digital signal processors).

In an example, the MLINC and radio frequency transmitter may be at least partially implemented as a computer, logic circuit, FPGA (field programmable logic gate array), microprocessor, microcontroller, vector processor, processor integrated core, CPU (e.g., with multiple cores), coprocessor (microprocessor supporting the CPU), GPU (graphics processing unit), and/or DSP.

For example, methods related to pipelining the data to be transmitted or the corresponding portions such as the information portion, the controlled portion and/or the other portions of the phase modulation mentioned in the detailed description may be used in the MLINC and the radio frequency transmitter in general. In this case, instead of an entire instruction being processed in one clock cycle of the processor used in the MLINC or the radio frequency transmitter, only a subtask thereof, e.g. a part of the data to be transmitted or also one or more portions of the phase modulation, is processed. The various subtasks of several commands are processed simultaneously. Further, methods in the sense of multithreading can be applied to the data to be transmitted or to the one or more portions of the phase modulation and further developments thereof, for example simultaneous multithreading of the data to be transmitted or of the one or more portions of the phase modulation. This makes it possible to achieve better processor utilization due to the parallel use of several processor cores. The processor included in the MLINC or the radio frequency transmitter can be connected to a buffer memory of the MLINC or the radio frequency transmitter, which can temporarily store the data to be transmitted or the one or more portions of the phase modulation before and/or after the processing of the data to be transmitted or the part thereof or the one or more portions of the phase modulation. The buffer memory may be integrated in a volatile memory device of the MLINC or the radio frequency transmitter, e.g. a DRAM, or a non-volatile memory device of the MLINC or the radio frequency transmitter, e.g. an SSD. This can increase the performance of the MLINC or radio frequency transmitter.

Unless otherwise defined, all technical and scientific terms used herein have the meaning that corresponds to the general understanding of the skilled person in the field of radio frequency technology relevant to the present disclosure; they are to be defined neither too broadly nor too narrowly. If technical terms are used incorrectly in the present disclosure and thus do not express the technical idea of the present disclosure, they are to be replaced by technical terms which convey a correct understanding to the skilled person. The general terms used in the present disclosure are to be interpreted on the basis of the definition found in the dictionary or corresponding to the technical jargon.

Although terms such as “first” or “second” etc. may be used to describe different components, these components are not to be limited to these terms. The above terms are merely intended to distinguish one component from another. For example, a first component may be referred to as a second component and a second component may be referred to as a first component.

In the present case, if a component is “connected to” or “communicates with” another component, this can mean that it is directly connected to or communicates with it; however, it should be noted that there may be another component in between. On the other hand, if it is said that a component is “directly connected” to another component or “communicates directly” with it, this means that there are no other components in between.

The method steps described herein should not be construed herein as having to be performed in any particular order, unless expressly or implicitly indicated otherwise, for example if these method steps cannot be interchanged for technical reasons. The method steps described herein can also be carried out directly, one after the other, consecutively and/or successively. However, there may also be other process steps in between.

### BRIEF DESCRIPTION OF THE DRAWINGS

Further objectives, features, advantages and possible applications are apparent from the following description of embodiments, which are not to be understood as limiting, with reference to the associated drawings. The same or similar elements in the drawings are always provided with the same or similar reference numbers. Detailed explanations of known functions and structures are omitted insofar as they detract from the invention.

The invention is explained in more detail by means of embodiments with reference to the attached schematic drawings with further details.

The drawings show in:

FIG. 1 a schematic illustration of a MLINC;

FIG. 2 a schematic illustration of an input signal of the MLINC;

FIG. 3 a schematic illustration of an intermediate signal of the MLINC;

FIG. 4 a schematic illustration of the output signal of the MLINC;

FIG. 5 a comparative schematic illustration between the MLINC and a conventional chireix amplifier; and

FIG. 6 a schematic illustration of a method of operation of the MLINC.

### DETAILED DESCRIPTION OF THE DRAWINGS

The MLINC 1 and the method S60 therefor will now be described in relation to the embodiments. Without being limited to this, specific details are explained to provide a deeper understanding of the invention.

To increase the data rate in wireless communication, either the modulation order or the modulation bandwidth must be increased. High modulation order requires circuits with high linearity and high modulation bandwidth requires circuits with high bandwidth. Both requirements must be met by powerful radio frequency (HF) power amplifiers (PA). In the development of RF PAs for cell phones and base stations, there is an inherent trade-off between linearity and efficiency.

Modern high data rate communication standards require linear amplification of the transmit signal in order to use complex modulation formats such as QAM and OFDM. To achieve the peak-to-average power ratio in these modulation formats, the power amplifiers must be driven down from their maximum output power, resulting in poor power efficiency. Typically, the power amplifiers are one of the most power hungry components of the radio frequency transmitter as they generate the high power signal for broadcasting. Therefore, increasing the power efficiency of the power amplifiers leads to longer battery life for cell phones and lower costs for the operation of cellular network base stations.

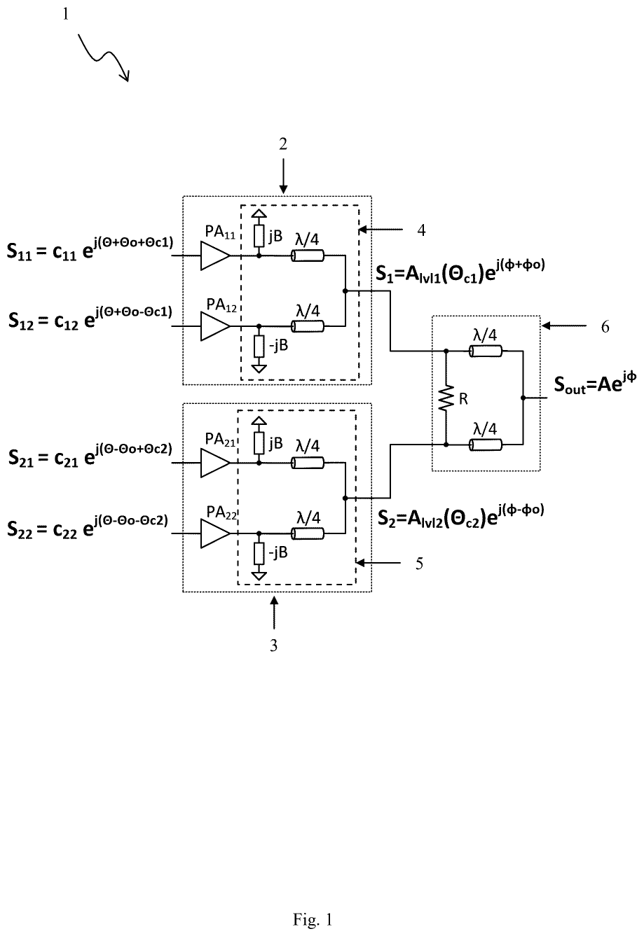

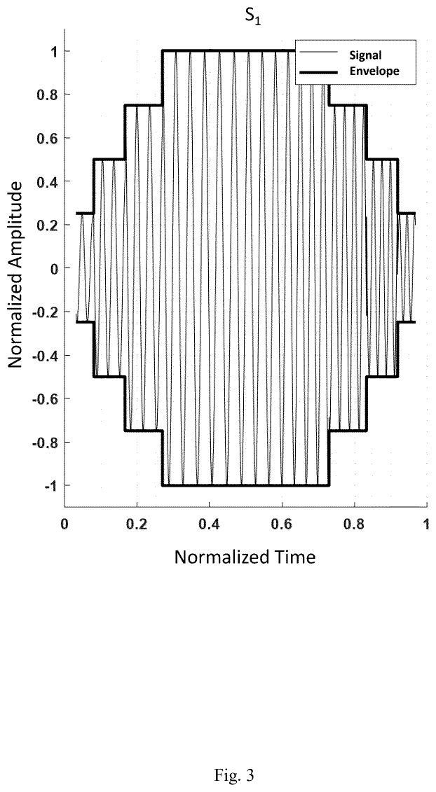

Such a compromise between linearity and efficiency is achieved by the MLINC 1 of FIG. 1, which uses linear amplification with non-linear components (LINC) to ensure linear amplification and establish efficiency by introducing discrete amplitude levels (see FIG. 3).

FIG. 1 shows a schematic illustration of an MLINC 1 with a combiner, such as a Wilkinson combiner. In particular, the amplitude levels are not generated by changing the supply voltage or the input amplitude of the PAs. To ensure linear amplification with increased modulation bandwidth, the control of the levels and the control of the outphasing angle (also called outphasing portion herein) must be synchronized. The control of the levels and the control of the phase-out angle are not carried out via two different paths, which would make synchronization more difficult and limit the maximum modulation bandwidth. The control is used in the phase modulation and thus the efficiency is not limited to the maximum efficiency of a conventional Doherty amplifier, for example. Due to the pure phase modulation without amplitude modulation, linear driver stages (with poor efficiency) can be omitted.

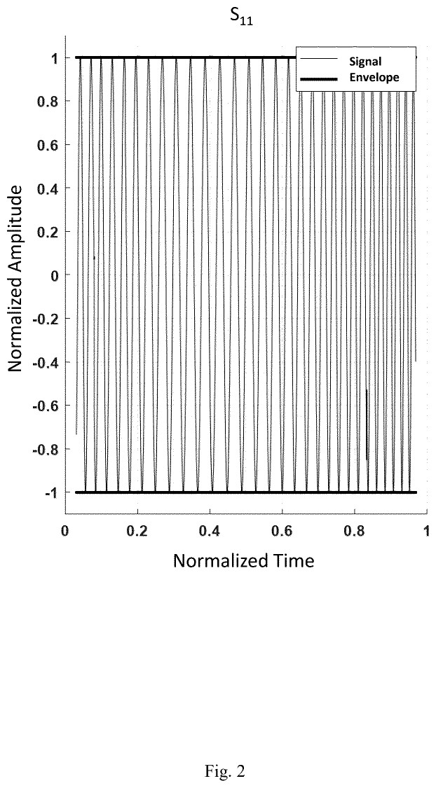

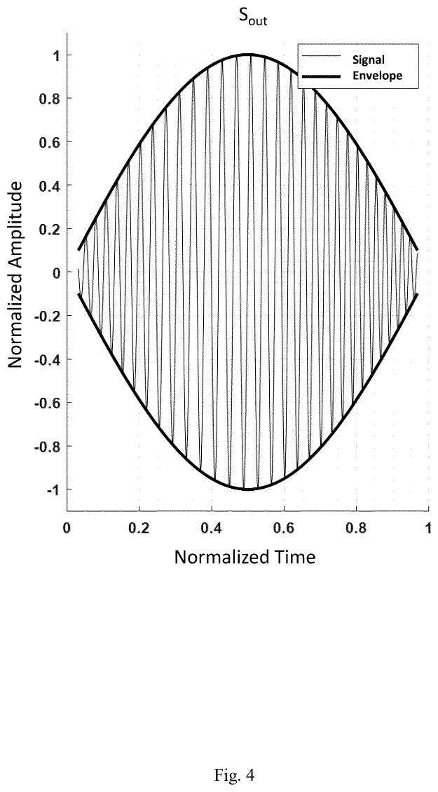

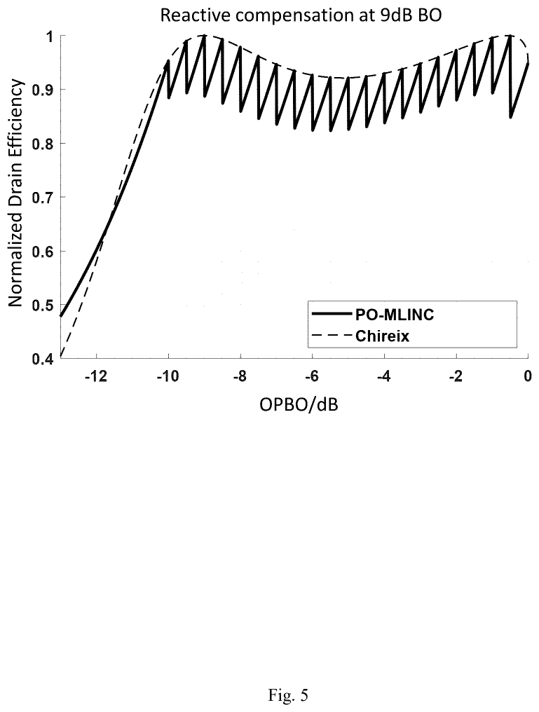

The MLINC 1 uses non-isolating outphasing amplifiers 2 and 3 to generate the levels for the MLINC 1. The levels are controlled by a discrete set of phases that can be calibrated prior to operation. Between two levels, the output amplitude is controlled linearly via LINC. In this way, the output can be controlled linearly over the entire dynamic range. FIG. 1 shows the implementation of the level generator by two outphasing amplifiers 2 and 3, preferably chireix amplifiers, which, however, can generally be realized by any non-isolating outphasing amplifier structure. To this end, FIGS. 2 to 4 indicate typical waveforms for corresponding signals at different tap points (input or output nodes) of the MLINC 1 with any 4-level design (cf. FIG. 3). The architecture of the MLINC 1 allows both the outphasing portion do and the level adjustment portion(s) θ_{c1}-θ_{c2} to be controlled by the same phase-modulated input signals S₁₁-S₂₂ provided to the amplifier elements PA₁₁-PA₂₂ and they are therefore synchronized from the outset, enabling broadband modulation. Furthermore, the non-isolating outphasing amplifiers 2 and 3 are potentially more efficient than Doherty amplifiers and therefore the MLINC 1 is more efficient than a conventional Doherty MLINC, as can be seen in FIG. 5, which contrasts efficiency curves for any 21-levels design of the MLINC1 with a conventional chireix amplifier circuit. This shows the high efficiency of the MLINC 1 described here.

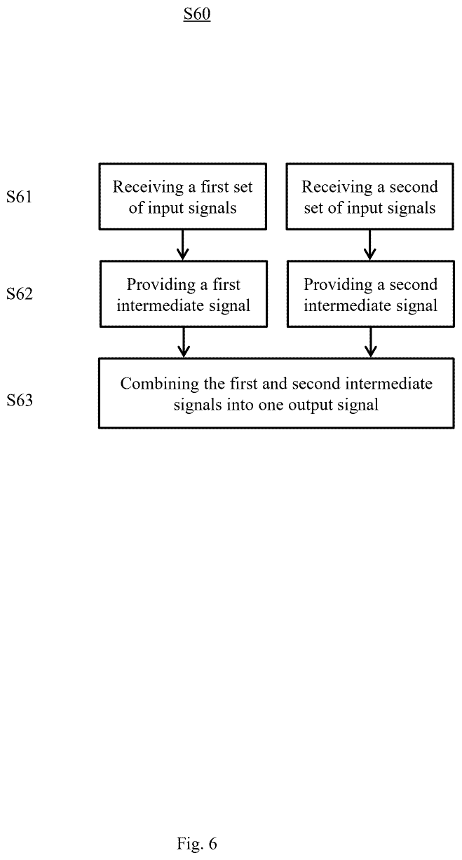

FIG. 6 describes the method S60 for operation of the MLINC 1 of FIG. 1. Here, the method S60 comprises receiving S61 a first set of input signals S₁₁ and S₁₂, where S₁₁=c₁₁ e^{j(θ+θo+θc1)} and S₁₂=c₁₂ e^{j(θ+θo-θc1)}, and a second set of input signals S₂₁ and S₂₂, where S₂₁=c₂₁ e^{j(θ-θo+θc2)} and S₂₂=c₂₂ e^{j(θ-θo-θc2)}. In an example, both the constant input portions c₁₁, c₁₂, c₂₁ and c₂₂ may be the same. In this example, the level adjustment portions θ_{c1} and θ_{c2} can also be the same.

At S62, the respective signals S₁₁ to S₂₂ (see signal curve in FIG. 2) are amplified by the respective amplifier clements PA₁₁ to PA₂₂ of the outphasing amplifiers 2 and 3. First and second intermediate signals S₁ and S₂ are provided from the amplified signals of the first and second set of input signals S₁₁ to S₂₂ by means of chireix combiners 4 and 5, with S₁=Aₗᵥₗ₁(θ_{c1})e^{j(ϕ+ϕo)} and S₂=Aₗᵥ₁₂(θ_{c2})e^{j(ϕ-ϕo)}. The first and second intermediate signals S₁ and S₂ each have a stepped envelope, with the amplitudes of the intermediate signals Aₗᵥₗ₁(θ_{c1}) and Aₗᵥₗ₂(θ_{c2}). The envelope depends on a controlled portion θ_{c1} and/or θ_{c2} of a phase modulation in the input signals S₁₁ to S₂₂. A chireix combiner 4 and 5 is used for this purpose, each of which has two complex conjugated passive components with respective admittance amounts B and λ/4 lines connected to them.

At S63, the first and second intermediate signals S₁ and S₂ are combined to form an output signal Sₒᵤₜ, with Sₒᵤₜ=Ae^{j(ϕ)}. The combination takes place via the combiner 6, which in FIG. 1 has a Wilkinson combiner with resistor R for isolation and two λ/4 lines. The output signal Sₒᵤₜ has a linearized envelope due to the phase symmetry of the first and second intermediate signals S₁ and S₂ (see e^{j(ϕo)} and e). ^{j(-ϕo)}

For a better understanding of the invention, the portions of the phase modulation are shown below. These portions are described herein as phase modulation portions and represent corresponding phase angles normalized to time. The output phase control portion θ represents the portion for controlling the output phase, where θ=ϕ+ϕ_{lvl,cm}, where ϕ represents the phase information of the symbol to be transmitted, i.c. the information portion of the data to be transmitted. ϕ_{lvl,cm} forms the phase compensation of the level-dependent phase distortion, which is the same for both outphasing amplifiers 2 and 3 (common mode). θₒ represents an Output amplitude control portion that adjusts the output amplitude A, with θₒ=ϕₒ+ϕ_{lvl,dm}, where ϕₒ represents the outphasing portion at the input of the isolating combiner 6. ϕ_{lvl,dm} forms the phase compensation of the level-dependent phase distortion, which is different for the two outphasing amplifiers 2 and 3 (differential mode).

Since both the control of the levels Aₗᵥₗ₁-Aₗᵥₗ₂ and the outphasing angle or outphasing portion ϕₒ is carried out by a phase-modulated signal, the entire signal generation is simplified, as the RF circuits only have to process constant envelope signals.

Due to the advantages described in the previous section, this invention enables wider bandwidth modulation with higher power efficiency while simplifying signal generation. As a result, the data rate of wireless communication standards can be increased and the power consumption of radio frequency transmitters can be reduced.

At this point, it should be noted that all the parts described above are claimed to be essential to the invention when viewed individually or in any combination, in particular the details shown in the drawings. Modifications thereof are familiar to the skilled person.

### LIST OF REFERENCE SIGNS

1 MLINC

2 First outphasing amplifier

3 Second outphasing amplifier

4 First Chireix combiner

5 Second Chireix combiner

6 Combiner

B Admittance amount

R Resistor

PA₁₁-PA₁₂ Amplifier elements

S₁₁-S₁₂ First set of input signals

S₂₁-S₂₂ Second set of input signals

S₁ First intermediate signal

S₂ Second intermediate signal

c₁₁-c₂₂ Constant input portions

Aₗᵥₗ₁-Aₗᵥₗ₂ Amplitudes of the intermediate signals

A Output amplitude

θ Output phase control portion

θₒ Output amplitude control portion

θ_{c1}-θ_{c2} Level adjustment portions

ϕ Information portion

ϕₒ Outphasing portion

1. A multilevel linear amplifier with non-linear components, for a radio frequency transmitter, the MLINC comprising:
a first outphasing amplifier adapted to receive a first set of input signals and to provide a first intermediate signal with a first stepped envelope depending on a controlled portion of a phase modulation in the first set of input signals;
a second outphasing amplifier adapted to receive a second set of input signals and to provide a second intermediate signal with a second stepped envelope depending on a controlled portion of a phase modulation in the second set of input signals; and
a combiner adapted to combine the first intermediate signal and the second intermediate signal into an output signal having an envelope linearized due to a phase symmetry of the first and second intermediate signals.

2. The MLINC according to claim 1, wherein the input signals of the first set of input signals and the second set of input signals have equal amplitudes.

3. The MLINC according to claim 1, wherein the input signals of the first set of input signals and/or the second set of input signals have a same constant envelope.

4. The MLINC according to claim 1, wherein the first set of input signals and the second set of input signals include phase modulated input signals.

5. The MLINC according to claim 1, wherein the controlled portion of the phase modulation in the first set of input signals is equal to the controlled portion of the phase modulation in the second set of input signals.

6. The MLINC according to claim 1, wherein the first outphasing amplifier and the second outphasing amplifier are non-isolating outphasing amplifiers.

7. The MLINC according to claim 1, wherein:
the first outphasing amplifier and the second outphasing amplifier each have input nodes forming inputs of the MLINC and an output node, and further each have a chireix combiner, and each of the chireix combiners comprise:
passive components having mutually complex conjugate admittances and each connected between a correspondent one of the input nodes and ground: and/or
λ/4 lines with respect to a carrier frequency λ of the radio frequency transmitter, each connected between the output node and a corresponding one of the input nodes.

8. The MLINC according to claim 7, wherein the combiner has input nodes each connected to one of the output nodes of the first outphasing amplifier and the second outphasing amplifier, an output node forming the output of the MLINC and an isolating power combiner.

9. The MLINC according to claim 1, wherein the first outphasing amplifier has a first set of amplifier elements and the second outphasing amplifier has a second set of amplifier elements, and the first set of amplifier elements and/or the second set of amplifier elements have equal amplifier elements in number of amplifier elements and/or type of amplifier elements.

10. A method of operating a multilevel linear amplifier with non-linear components (MLINC), for a radio frequency transmitter, the method comprising:
receiving a first and second set of input signals;
providing first and second intermediate signals each having a step-shaped envelope depending on a controlled portion of a phase modulation in a corresponding one of the first and second sets of input signals; and
combining the first and second intermediate signals into an output signal having an envelope linearized due to a phase symmetry of the first and second intermediate signals.
